(19) United States
(12) Patent Application Publication
(10) Pub. No.: US 2025/0105183 A1
(43) Pub. Date: Mar. 27, 2025

(54) SEMICONDUCTOR CHIP AND SEMICONDUCTOR PACKAGE

(71) Applicant: SAMSUNG ELECTRONICS CO., LTD., Suwon-si (KR)

(72) Inventors: Hyung Chul SHIN, Suwon-si (KR); Won IL LEE, Suwon-si (KR)

(21) Appl. No.: 18/817,305

(22) Filed: Aug. 28, 2024

(30) Foreign Application Priority Data
Sep. 27, 2023 (KR) 10-2023-0131186

(51) Int. Cl. H01L 23/00; H01L 23/31; H01L 23/48; H01L 25/18

(52) U.S. Cl. CPC H01L 24/06; H01L 24/08; H01L 24/09; H01L 25/18; H01L 23/3107; H01L 23/481; H01L 24/05; H01L 2224/05555; H01L 2224/06051; H01L 2224/06515; H01L 2224/08146; H01L 2224/09181

(57) ABSTRACT

According to example embodiments of the present inventive concept, a semiconductor chip includes: a semiconductor substrate including a first surface and a second surface that is opposite to the first surface; a through-via disposed in the semiconductor substrate; a first bonding pad disposed on the first surface of the semiconductor substrate and electrically connected to the through-via; a first dummy pad disposed on the first surface of the semiconductor substrate and insulated from the through-via; and a second bonding pad disposed on the second surface of the semiconductor substrate and electrically connected to the through-via, wherein a first maximum width of the first bonding pad is greater than a second maximum width in a first direction of the first dummy pad and is smaller than a third maximum width in a second direction of the first dummy pad, and wherein the first direction is substantially perpendicular to the second direction.

### CROSS-REFERENCE TO RELATED APPLICATION

This application claims priority under 35 USC § 119 to Korean Patent Application No. 10-2023-0131186 filed on Sep. 27, 2023, in the Korean Intellectual Property Office, the disclosure of which is incorporated by reference herein in its entirety.

### TECHNICAL FIELD

Example embodiments of the present inventive concept relate to a semiconductor chip and a semiconductor package.

### DISCUSSION OF THE RELATED

A die-to-wafer bonding process for manufacturing a multi-chip package in which a plurality of semiconductor chips are stacked may be performed in a hybrid bonding scheme in which pads are bonded to each other and insulating films are bonded to each other, rather than using a solder bump.

Generally, the pad may be formed in a damascene process and may be planarized in a chemical mechanical polishing (CMP) process. In this regard, for the hybrid bonding, it is desirable to measure a value of a dishing that occurs on an upper surface of the pad.

### SUMMARY

According to example embodiments of the present inventive concept, a semiconductor chip includes: a semiconductor substrate including a first surface and a second surface that is opposite to the first surface; a through-via disposed in the semiconductor substrate; a first bonding pad disposed on the first surface of the semiconductor substrate and electrically connected to the through-via; a first dummy pad disposed on the first surface of the semiconductor substrate and insulated from the through-via; and a second bonding pad disposed on the second surface of the semiconductor substrate and electrically connected to the through-via, wherein a first maximum width of the first bonding pad is greater than a second maximum width in a first direction of the first dummy pad and is smaller than a third maximum width in a second direction of the first dummy pad, and wherein the first direction is substantially perpendicular to the second direction.

According to example embodiments of the present inventive concept, a semiconductor package includes: a first semiconductor chip including: a first bonding insulating film; and a first bonding pad and a first dummy pad disposed in the first bonding insulating film; and a second semiconductor chip including: a second bonding insulating film disposed on the first bonding insulating film; and a second bonding pad disposed in the second bonding insulating film and in contact with the first bonding pad, wherein a size of an area of the first bonding pad is substantially equal to a size of an area of the first dummy pad, wherein a first maximum width of the first bonding pad is different from each of a second maximum width in a first direction of the first dummy pad and a third maximum width in a second direction of the first dummy pad, and wherein the first direction is substantially perpendicular to the second direction.

According to example embodiments of the present inventive concept, a semiconductor package includes: a first semiconductor chip; and a chip stack including a plurality of second semiconductor chips that are stacked on the first semiconductor chip, wherein each of the plurality of second semiconductor chips includes: a semiconductor substrate including a first surface and a second surface that is opposite to the first surface; a through-via extending through the semiconductor substrate; a first bonding insulating film disposed on the first surface of the semiconductor substrate; a first bonding pad disposed in the first bonding insulating film and electrically connected to the through-via; a first dummy pad disposed in the first bonding insulating film and insulated from the through-via; a second bonding insulating film disposed on the second surface of the semiconductor substrate; and a second bonding pad disposed in the second bonding insulating film and electrically connected to the through-via, wherein the first bonding pad of a first second semiconductor chip of the plurality of second semiconductor chips and the second bonding pad of a second semiconductor chip of the plurality of second semiconductor chips are adjacent to each other and are in contact with each other, wherein a size of an area of the first bonding pad is substantially equal to a size of an area of the first dummy pad, and wherein the first dummy pad includes a portion that has a width in a first direction that is substantially equal to a second maximum width of the first dummy pad that is smaller than a first maximum width of the first bonding pad.

### BRIEF DESCRIPTION OF DRAWINGS

The above and features of the present inventive concept will become more apparent by describing in detail example embodiments thereof with reference to the attached drawings, in which:

FIG. 1 is a diagram for illustrating a semiconductor package according to example embodiments of the present inventive concept;

FIG. 2 and FIG. 5 are enlarged views of an A area in FIG. 1;

FIG. 3 and FIG. 4 are diagrams for illustrating a first upper dummy pad according to example embodiments of the present inventive concept;

FIG. 5 is an enlarged view of a B area in FIG. 1;

FIG. 6 is a diagram for illustrating a second upper dummy pad according to example embodiments of the present inventive concept;

FIG. 7 is an enlarged view of a C area in FIG. 1;

FIG. 8 is an enlarged view of the A area in FIG. 1;

FIG. 9 is an enlarged view of the B area in FIG. 1.

FIG. 10 and FIG. 11 are diagrams for illustrating a first lower dummy pad according to example embodiments of the present inventive concept;

FIG. 12 is an enlarged view of the C area in FIG. 1;

FIG. 13 is a diagram for illustrating a second lower dummy pad according to example embodiments of the present inventive concept;

FIG. 14 and FIG. 15 are diagrams for illustrating an effect of the semiconductor package according to example embodiments of the present inventive concept;

FIG. 16 is a plan view for illustrating a semiconductor package according to example embodiments of the present inventive concept;

FIG. 17 is a cross-sectional view as cut along a line I-I in FIG. 16; and

FIGS. 18, 19 and 20 are plan views for illustrating a semiconductor package according to example embodiments of the present inventive concept.

### DETAILED DESCRIPTIONS OF THE EMBODIMENTS

Hereinafter, example embodiments according to the present inventive concept will be described with reference to the attached drawings.

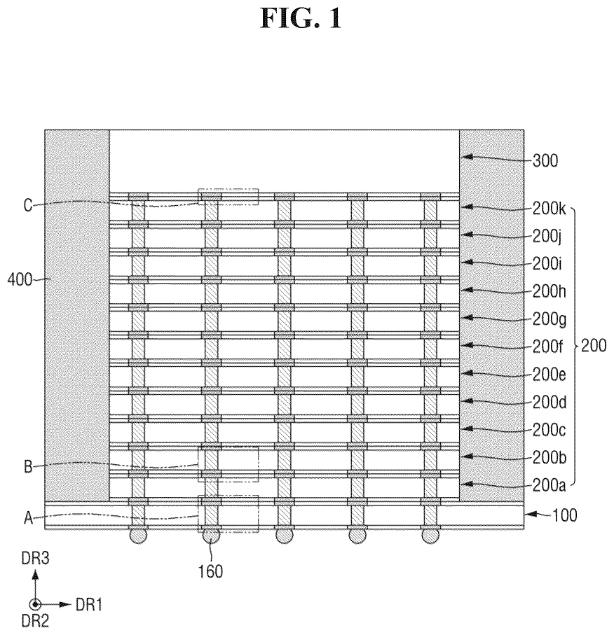

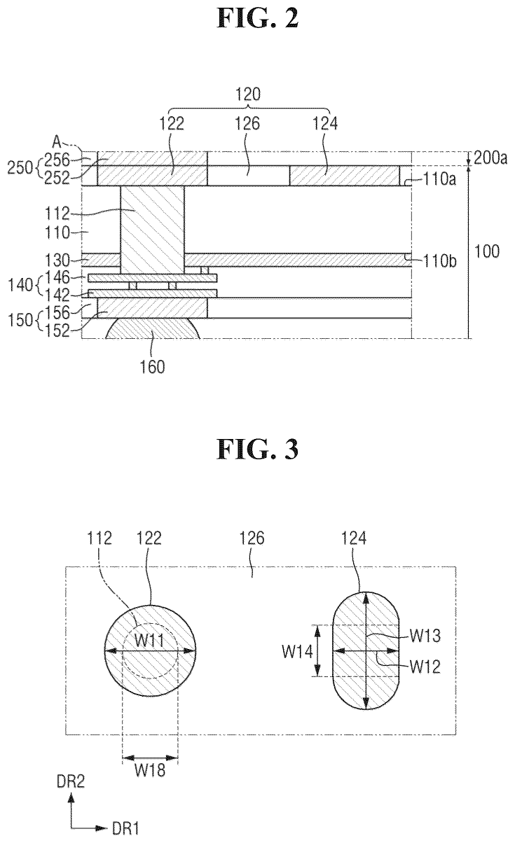

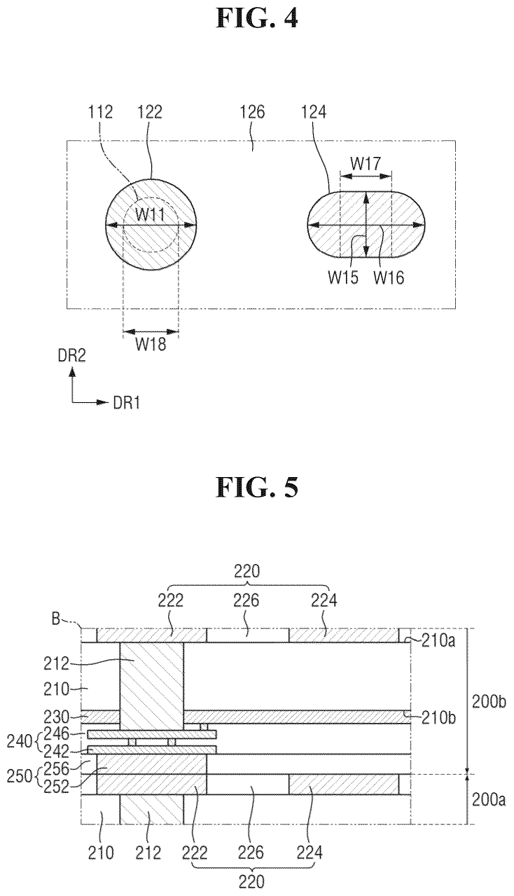

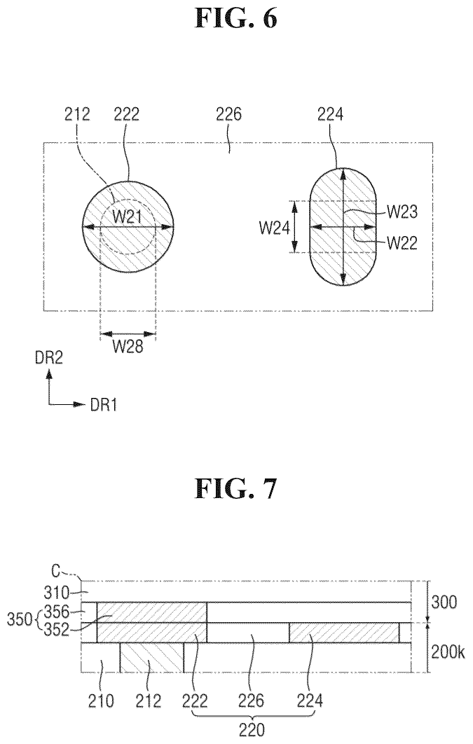

FIG. 1 is a diagram for illustrating a semiconductor package according to example embodiments of the present inventive concept. FIG. 2 and FIG. 5 are enlarged views of an A area in FIG. 1. FIG. 3 and FIG. 4 are diagrams for illustrating a first upper dummy pad according to example embodiments of the present inventive concept. FIG. 5 is an enlarged view of a B area in FIG. 1. FIG. 6 is a diagram for illustrating a second upper dummy pad according to example embodiments of the present inventive concept. FIG. 7 is an enlarged view of a C area in FIG. 1.

Referring to FIGS. 1 to 7, a semiconductor package according to example embodiments may include a first semiconductor chip 100, a first connection terminal 160, a chip stack 200 including second semiconductor chips 200a to 200k, a third semiconductor chip 300, and a molding layer 400.

Each of the first semiconductor chip 100 and the second semiconductor chips 200a to 200k may be a buffer chip, a memory semiconductor chip, or a logic chip. For example, the first semiconductor chip 100 and chip stack 200 may constitute a high bandwidth memory (HBM), and the first semiconductor chip 100 may be a buffer chip. For example, each of the second semiconductor chips 200a to 200k may be a memory semiconductor chip. The first semiconductor chip 100 may function as a buffer die, and each of the second semiconductor chips 200a to 200k may function as a core die. The buffer die may also be referred to as an interface die, a base die, a logic die, a master die, etc. while the core die may also be referred to as a memory die, a slave die, etc.

The logic chip may be, for example, a CPU (Central Processing Unit), a GPU (Graphic Processing Unit), a FPGA (Field-Programmable Gate Array), an application processor (AP) such as a digital signal processor, a cryptographic processor, a microprocessor, a micro controller, and an ASIC (Application-Specific IC). However, the present inventive concept is not limited thereto. The memory semiconductor chip may be, for example, a volatile memory semiconductor chip such as DRAM (Dynamic Random Access Memory) or SRAM (Static Random Access Memory), or may be a non-volatile memory semiconductor chip such as PRAM (Phase-change Random Access Memory), MRAM (Magnetoresistive Random Access Memory), FeRAM (Ferroelectric Random Access Memory) or RRAM (ResistiveRandom Access Memory).

The third semiconductor chip 300 may be a memory semiconductor chip or a dummy semiconductor chip. Hereinafter, an example in which the third semiconductor chip 300 is a dummy semiconductor chip will be described. However, the present inventive concept is not limited thereto.

Referring to FIG. 1 and FIG. 2, the first semiconductor chip 100 may include a first semiconductor substrate 110, a first through-via 112, a first upper bonding layer 120, a first semiconductor device layer 130, a first chip wiring layer 140, and a first lower bonding layer 150.

The first semiconductor substrate 110 may include a first surface 110a and a second surface 110b which are opposite to each other. A third direction DR3 may intersect a first direction DR1 and a second direction DR2. The first direction DR1 and the second direction DR2 may be directions that extend parallel to the first surface 110a of the first semiconductor substrate 110 and the second surface 110b of the first semiconductor substrate 110. The third direction DR3 may be a direction that is perpendicular to the first surface 110a of the first semiconductor substrate 110. Hereinafter, a top surface, an upper surface, an upper portion, a lower surface, a lower portion, and a bottom surface are defined along the third direction DR3. For example, the first surface 110a of the first semiconductor substrate 110 is an upper surface of the first semiconductor substrate 110.

The first through-via 112 may be disposed in the first semiconductor substrate 110. The first through-via 112 may extend through the first semiconductor substrate 110.

The first upper bonding layer 120 is disposed on the first surface 110a of the first semiconductor substrate 110. The first upper bonding layer 120 may include a first upper bonding insulating film 126, and a first upper bonding pad 122 and a first upper dummy pad 124 that are disposed in the first upper bonding insulating film 126.

The first upper bonding pad 122 is electrically connected to the first through-via 112. For example, the first upper bonding pad 122 may contact the first through-via 112. The first upper dummy pad 124 is not electrically connected to the first through-via 112. The first upper dummy pad 124 does not contact the first through-via 112. In addition, the first upper dummy pad 124 may be in contact with a dummy through-via extending through the first semiconductor substrate 110. Within the first upper bonding insulating film 126, a position of the first upper bonding pad 122 and a position of the first upper dummy pad 124 may vary.

Referring to FIG. 3 and FIG. 4, in a plan view including the first direction DR1 and the second direction DR2, a size of an area of the first upper bonding pad 122 is substantially the same as a size of an area of the first upper dummy pad 124, and the first upper bonding pad 122 and the first upper dummy pad 124 have different shapes from each other. Hereinafter, “substantially the same size” may mean a difference in size of 10% or smaller. For example, the first upper bonding pad 122 may have a circular shape, and the first upper dummy pad 124 may have an elliptical shape. The shape of the first upper dummy pad 124 may be various, for example, a rectangle.

For example, referring to FIG. 3, the first upper dummy pad 122 may have the circular shape, and the first upper dummy pad 124 may have the elliptical shape having a major axis in the second direction DR2.

A maximum width W12 of the first upper dummy pad 124 in the first direction DR1 (for example, a direction that is perpendicular to a direction in which the major axis of the first upper dummy pad 124 extends) is different from a maximum width W13 of the first upper dummy pad 124 in the second direction DR2 (for example, a direction in which the major axis of the first upper dummy pad 124 extends). The maximum width W12 of the first upper dummy pad 124 is smaller than the maximum width W13 of the first upper dummy pad 124. For example, the maximum width W13 of the first upper dummy pad 124 may be about 1.6 times of the maximum width W12 of the first upper dummy pad 124. The first upper dummy pad 124 may include an area with a maximum width of W12 that is constant. For example, a width W14 in the second direction DR2 of the area, which has the maximum width of W12 that is constant, may be about 0.2 times of the maximum width W13 of the first upper dummy pad 124. For example, the width W14 may be substantially equal to the maximum width W12.

A maximum width W11 of the first upper bonding pad 122 may be larger than a width W18 of the first through-via 112. The maximum width W12 of the first upper dummy pad 124 may be larger than the width W18 of the first through-via 112.

The maximum width W12 of the first upper dummy pad 124 is smaller than the maximum width W11 of the first upper bonding pad 122, and the maximum width W13 of the first upper dummy pad 124 is larger than the maximum width W11 of the first upper bonding pad 122. For example, the maximum width W12 of the first upper dummy pad 124 may be in a range of about 0.5 to about 0.8 times of the maximum width W11 of the first upper bonding pad 122.

For example, referring to FIG. 4, the first upper dummy pad 124 may have a circular shape, and the first upper dummy pad 124 may have an elliptical shape having a major axis extending in the first direction DR1.

A maximum width W16 of the first upper dummy pad 124 in the first direction DR1 (for example, the direction in which the first upper dummy pad 124 extends in an elongate manner) is different from a maximum width W15 of the first upper dummy pad 124 in the second direction DR2 (for example, the direction that is perpendicular to the direction in which the first upper dummy pad 124 extends in an elongate manner). The maximum width W15 of the first upper dummy pad 124 is smaller than the maximum width W16 of the first upper dummy pad 124. For example, the maximum width W16 of the first upper dummy pad 124 may be about 1.6 times of the maximum width W15 of the first upper dummy pad 124. The first upper dummy pad 124 may include an area that has a maximum width of W15 that is constant. For example, a width W17 in the first direction DR1 of the area, which has the maximum width of W15 that is constant, may be about 0.2 times of the maximum width W16 of the first upper dummy pad 124.

The maximum width W15 of the first upper dummy pad 124 may be larger than the width W18 of the first through-via 112.

The maximum width W15 of the first upper dummy pad 124 is smaller than the maximum width W11 of the first upper bonding pad 122. The maximum width W16 of the first upper dummy pad 124 is larger than the maximum width W11 of the first upper bonding pad 122. For example, the maximum width W15 of the first upper dummy pad 124 may be in a range of about 0.5 to about 0.8 times of the maximum width W11 of the first upper bonding pad 122.

The direction in which the major axis of the first upper dummy pad 124 extends is not limited to what is shown in the drawing. The major axis of the first upper dummy pad 124 may extend in any specific direction that is parallel to the plane including the first direction DR1 and the second direction DR2. The major axis of the first upper dummy pad 124 may extend in any specific direction that is parallel to the plane including the first direction DR1 and the second direction DR2, and the maximum width in any specific direction of the first upper dummy pad 124 is greater than the maximum width of the first upper dummy pad 124 in the direction perpendicular to any specific direction. The first upper dummy pad 124 includes the area whose the maximum width is constant and is substantially equal to the maximum width in any specific direction of the first upper dummy pad 124. The maximum width of the first upper dummy pad 124 in any specific direction may be about 1.6 times of the maximum width of the first upper dummy pad 124 in the direction that is perpendicular to any specific direction. The area of the first upper dummy pad 124 whose the maximum width is constant and is substantially equal to the maximum width in any specific direction of the first upper dummy pad 124 may have a width in any specific direction which may be about 0.2 times of the maximum width of the first upper dummy pad 124 in any specific direction. The maximum width of the first upper dummy pad 124 in the direction that is perpendicular to any specific direction may be greater than the maximum width W18 of the first through-via 112, and may be in a range of about 0.5 times to about 0.8 times of the maximum width W11 of the first upper bonding pad 122.

Referring again to FIGS. 1 to 7, the first semiconductor device layer 130 may be disposed on the second surface 110b of the first semiconductor substrate 110. The second surface 110b of the first semiconductor substrate 110 may be an active surface on which the first semiconductor device layer 130 is formed.

The first chip wiring layer 140 may be disposed on the first semiconductor device layer 130. The first chip wiring layer 140 may include a first chip inter-wiring insulating film 146 and a first chip wiring 142 that is disposed in the first chip inter-wiring insulating film 146. The first chip wiring 142 may include multi-layered wiring patterns and vias connecting the wiring patterns to each other.

The first chip wiring layer 140 may be electrically connected to the first semiconductor device layer 130. For example, the first semiconductor device layer 130 may contact the uppermost wiring of the first chip wiring 142. The arrangement, the number of layers of each of, the number, etc. of the first chip wirings 142 as shown in the drawing are only illustrative and are not limited thereto.

The first lower bonding layer 150 may be disposed on the first chip wiring layer 140. The first lower bonding layer 150 may include a first bonding insulating film 156 and the first lower bonding pad 152 that is disposed in the first bonding insulating film 156.

The first lower bonding layer 150 may be electrically connected to the first chip wiring layer 140. The first lower bonding pad 152 may contact the lowermost wiring of the first chip wiring 142, for example.

The first connection terminal 160 may be disposed on the first lower bonding layer 150. The first connection terminal 160 may be disposed on the first lower bonding pad 152. The first connection terminal 160 may be electrically connected to the first semiconductor chip 100. For example, the first connection terminal 160 may contact the first lower bonding pad 152.

The first connection terminal 160 may include, for example, a solder ball, a bump, an under bump metallurgy (UBM), etc. The first connection terminal 160 may include a metal such as tin (Sn). However, the present inventive concept is not limited thereto.

The chip stack 200 is disposed on the first semiconductor chip 100. The chip stack 200 may include a plurality of second semiconductor chips 200a to 200k stacked on each other in the third direction DR3. The number of the second semiconductor chips 200a to 200k as shown in the drawing is only illustrative and is not limited thereto. For example, a width of the chip stack 200 may be larger than a width of the first semiconductor chip 100.

Each of the second semiconductor chips 200a to 200k may include a second semiconductor substrate 210, a second through-via 212, a second upper bonding layer 220, a second semiconductor device layer 230, a second chip wiring layer 240 and a second lower bonding layer 250.

The second semiconductor substrate 210 may include a third surface 210a and a fourth surface 210b which are opposite to each other. The fourth surface 210b of the second semiconductor substrate 210 of the lowermost second semiconductor chip 200a of the chip stack 200 may face the first surface 110a of the first semiconductor substrate 110.

The second through-via 212 may be disposed in the second semiconductor substrate 210. The second through-via 212 may extend through the second semiconductor substrate 210.

Each of the first through-via 112 and the second through-via 212 may include at least one of, for example, Cu alloys such as Cu, CuSn, CuMg, CuNi, CuZn, CuPd, CuAu, CuRe, CuW, etc., W, W alloys, Ni, Ru, and Co. However, the present inventive concept is not limited thereto.

The second upper bonding layer 220 is disposed on the third surface 210a of the second semiconductor substrate 210. The second upper bonding layer 220 may include a second upper bonding insulating film 226, and a second upper bonding pad 222 and a second upper dummy pad 224 that are disposed in the second upper bonding insulating film 226.

The second upper bonding pad 222 is electrically connected to the second through-via 212. For example, the second upper bonding pad 222 may contact the second through-via 212. The second upper dummy pad 224 is not electrically connected to the second through-via 212. The second upper dummy pad 224 does not contact the second through-via 212. In addition, the second upper dummy pad 224 may contact a dummy through-via extending through the second semiconductor substrate 210. Within the second upper bonding insulating film 226, a position of the second upper bonding pad 222 and a position of the second upper dummy pad 224 may vary. At least a portion of the first upper dummy pad 124 may overlap with the second upper dummy pad 224 in the third direction DR3, and might not overlap with the second upper bonding pad 222 in the third direction DR3.

Referring to FIG. 6, in a plan view including the first direction DR1 and the second direction DR2, a size of an area of the second upper bonding pad 222 is substantially equal to a size of an area of the second upper dummy pad 224, and the second upper bonding pad 222 and the second upper dummy pad 224 have different shapes from each other. For example, the second upper bonding pad 222 may have a circular shape, and the second upper dummy pad 224 may have an elliptical shape. The shape of the second upper dummy pad 224 may be various, such as a rectangle.

For example, the second upper dummy pad 224 may have an elliptical shape having a major axis extending in the second direction DR2. Descriptions about the second upper bonding pad 222, the second upper dummy pad 224, and widths W21, W22, W23, W24, and W28 may be substantially the same as the descriptions about the first upper bonding pad 122, the first upper dummy pad 124 and the widths W11, W12, W13, W14, and W18, respectively, as set forth above with reference to FIG. 3.

The direction in which the major axis off the second upper dummy pad 224 extends is not limited to what is shown in the drawing. The major axis of the second upper dummy pad 224 may extend in any direction that is parallel to the plane including the first direction DR1 and the second direction DR2.

The second semiconductor device layer 230 may be disposed on the fourth surface 210b of the second semiconductor substrate 210. The fourth surface 210b of the second semiconductor substrate 210 may be an active surface on which the second semiconductor device layer 230 is formed.

Each of the first semiconductor device layer 130 and the second semiconductor device layer 230 may include various microelectronic elements, for example, a metal-oxide-semiconductor field (MOSFET) such as a complementary metal-insulator-semiconductor transistor (CMOS transistor), s system LSI (large scale integration), flash memory, DRAM, SRAM, EEPROM, PRAM, MRAM, or RERAM, an image sensor such as CIS (CMOS imaging sensor), MEMS (micro-electro-mechanical system), an active element, a passive element, etc.

The second chip wiring layer 240 may be disposed on the second semiconductor device layer 230. The second chip wiring layer 240 may include a second chip inter-wiring insulating film 246 and a second chip wiring 242 that is disposed in the second chip inter-wiring insulating film 246. The second chip wiring 242 may include multi-layered wiring patterns and vias connecting the wiring patterns to each other. The second chip wiring layer 240 may be electrically connected to the second semiconductor device layer 230. For example, the second semiconductor device layer 230 may contact the uppermost wiring of the second chip wiring 242. The arrangement, the number of layers of each of, the number, etc. of the second chip wirings 242 as shown in the drawing are for illustrative purposes only and are not limited thereto.

Each of the first and second chip wirings 142 and 242 may include, but might not be limited to, at least one of tungsten (W), aluminum (Al), and copper (Cu).

The second lower bonding layer 250 may be disposed on the second chip wiring layer 240. The second lower bonding layer 250 may include a second lower bonding insulating film 256 and a second lower bonding pad 252 that is disposed in the second lower bonding insulating film 256.

The second lower bonding layer 250 may be electrically connected to the second chip wiring layer 240. The second lower bonding pad 252 may contact the lowermost wiring of the second chip wiring 242, for example.

The third semiconductor chip 300 is disposed on the chip stack 200. For example, a width of the third semiconductor chip 300 may be substantially the same as the width of the chip stack 200. A thickness of the third semiconductor chip 300 may be different from a thickness of each of the second semiconductor chips 200a to 200k.

The third semiconductor chip 300 may include a third semiconductor substrate 310 and a third lower bonding layer 350. The third semiconductor chip 300 may be, for example, a semiconductor substrate that does not include a circuit layer.

Each of the first to third semiconductor substrates 110, 210, and 310 may be made of, for example, bulk silicon or SOI (silicon-on-insulator). In addition, as an example, each of the first to third semiconductor substrates 110, 210, and 310 may be a silicon substrate or may include a material other than silicon, such as silicon germanium, silicon germanium on insulator (SGOI), indium antimonide, lead telluride compound, indium arsenide, indium phosphide, gallium arsenide and/or gallium antimonide. However, the present inventive concept is not limited thereto.

The third lower bonding layer 350 may be disposed between the third semiconductor substrate 310 and the topmost second semiconductor chip 200k of the chip stack 200. The third lower bonding layer 350 may include a third lower bonding insulating film 356 and a third lower bonding pad 352 that is disposed in the third lower bonding insulating film 356.

Each of the first and second upper bonding pads 122 and 222, the first and second upper dummy pads 124 and 224, and the first to third lower bonding pads 152, 252, and 352 may be made of a metal material, for example, at least one of copper (Cu), tungsten (W), aluminum (Al), tungsten nitride (WN), tantalum nitride (TaN), and/or titanium nitride (TIN). However, the present inventive concept is not limited thereto.

Each of the first and second upper bonding insulating films 126 and 226, and the first to third lower bonding insulating films 156, 256, and 356 may be made of an insulating material, such as SiO, SiN, SiCN, SiOC, SiON and SiOCN. However, the present inventive concept is not limited thereto.

The chip stack 200 and the first semiconductor chip 100 may be bonded to each other. Ones of the second semiconductor chips 200a to 200k that are adjacent to each other may be bonded to each other. The third semiconductor chip 300 and the chip stack 200 may be bonded to each other. The second lower bonding layer 250 of the second semiconductor chip 200a and the first upper bonding layer 120 of the first semiconductor chip 100 may be bonded to each other in a hybrid bonding scheme. The second lower bonding layer 250 of each of the second semiconductor chips 200b to 200k (even number-th semiconductor chips) and the second upper bonding layer 220 of each of the second semiconductor chips 200a to 200j (odd number-th semiconductor chips) may be bonded to each other in a hybrid bonding scheme. The third lower bonding layer 350 of the third semiconductor chip 300 and the second upper bonding layer 220 of the second semiconductor chip 200k may be bonded to each other in a hybrid bonding scheme.

For example, the second lower bonding layer 250 of the second semiconductor chip 200a and the first upper bonding layer 120 of the first semiconductor chip 100 may be in contact with each other. The second lower bonding pad 252 of the second semiconductor chip 200a and the first upper bonding pad 122 of the first semiconductor chip 100 may be bonded to each other. For example, the second lower bonding pad 252 of the second semiconductor chip 200a and the first upper bonding pad 122 of the first semiconductor chip 100 may be directly bonded to each other while contacting each other. The second lower bonding insulating film 256 of the second semiconductor chip 200a and the first upper bonding insulating film 126 of the first semiconductor chip 100 may be bonded to each other. For example, the second lower bonding insulating film 256 of the second semiconductor chip 200a and the first upper bonding insulating film 126 of the first semiconductor chip 100 may be directly bonded to each other while contacting each other. The second lower bonding pad 252 of the second semiconductor chip 200a and the first upper bonding pad 122 of the first semiconductor chip 100 may be bonded to each other in a copper-copper bonding manner. The second lower bonding insulating film 256 of the second semiconductor chip 200a and the first upper bonding insulating film 126 of the first semiconductor chip 100 may be bonded to each other in a dielectric-dielectric bonding scheme. Via the second lower bonding pad 252 of the second semiconductor chip 200a and the first upper bonding pad 122 of the first semiconductor chip 100, the second semiconductor chip 200a and the first semiconductor chip 100 may be electrically connected to each other.

The second lower bonding layer 250 may be disposed on an adjacent second upper bonding layer 220. For example, the second lower bonding layer 250 and the second upper bonding layer 220 that are adjacent to each other may be in contact with each other. The second lower bonding pad 252 and the second upper bonding pad 222, which are adjacent to each other, may be bonded to each other. For example, the second lower bonding pad 252 and the second upper bonding pad 222, which are adjacent to each other, may be directly bonded to each other while contacting each other. The second lower bonding insulating film 256 and the second upper bonding insulating film 226 that are adjacent to each other may be bonded to each other. For example, the second lower bonding insulating film 256 and the second upper bonding insulating film 226 that are adjacent to each other may be directly bonded to each other while contacting each other. The second lower bonding pad 252 and the second upper bonding pad 222 which are adjacent to each other may be bonded to each other in a copper-copper bonding scheme. The second lower bonding insulating film 256 and the second upper bonding insulating film 226 which are adjacent to each other may be bonded to each other in a dielectric-dielectric bonding scheme. Ones of the second semiconductor chips 200a to 200k that are adjacent to each other may be electrically connected to each other via the second lower bonding pad 252 and the second upper bonding pad 222 adjacent to each other.

The third lower bonding layer 350 may be disposed on the second upper bonding layer 220 of the second semiconductor chip 200k. For example, the second upper bonding layer 220 of the second semiconductor chip 200k and the third lower bonding layer 350 of the third semiconductor chip 300 may be in contact with each other. The second upper bonding pad 222 of the second semiconductor chip 200k and the third lower bonding pad 352 of the third semiconductor chip 300 may be bonded to each other. For example, the second upper bonding pad 222 of the second semiconductor chip 200k and the third lower bonding pad 352 of the third semiconductor chip 300 may be directly bonded to each other while contacting each other. The second upper bonding insulating film 226 of the second semiconductor chip 200k and the third lower bonding insulating film 356 of the third semiconductor chip 300 may be bonded to each other. For example, the second upper bonding insulating film 226 of the second semiconductor chip 200k and the third lower bonding insulating film 356 of the third semiconductor chip 300 may be directly bonded to each other while contacting each other. The second upper bonding pad 222 of the second semiconductor chip 200k and the third lower bonding pad 322 of the third semiconductor chip 300 may be bonded to each other in a copper-copper bonding scheme. The second upper bonding insulating film 226 of the second semiconductor chip 200k and the third lower bonding insulating film 326 of the third semiconductor chip 300 may be bonded to each other in a dielectric-dielectric bonding scheme. Via the second upper bonding pad 222 of the second semiconductor chip 200k and the third lower bonding pad 322 of the third semiconductor chip 300, the second semiconductor chip 200k and the third semiconductor chip 300 may be electrically connected to each other.

In example embodiments of the present inventive concept, the first semiconductor chip 100 may include the first upper dummy pad 124. Each of the second semiconductor chips 200a to 200k may include the second upper dummy pad 224. The first upper dummy pad 124 may contact the second lower bonding insulating film 256 of the second semiconductor chip 200a adjacent thereto in the third direction DR3. The second upper dummy pad 224 may contact the second lower bonding insulating film 256 adjacent thereto in the third direction DR3.

The molding layer 400 may be disposed on the first semiconductor chip 100. For example, the molding layer 400 may surround an entirety of a side surface of the chip stack 200 and a side surface of the third semiconductor chip 300 and cover an upper surface of the first semiconductor chip 100. The molding layer 400 might not cover, for example, an upper surface of the third semiconductor chip 300 so as to be exposed. In another example, the molding layer 400 may cover the upper surface of the third semiconductor chip 300.

The molding layer 400 may include, for example, an insulating polymer material such as EMC (epoxy molding compound). However, the present inventive concept is not limited thereto.

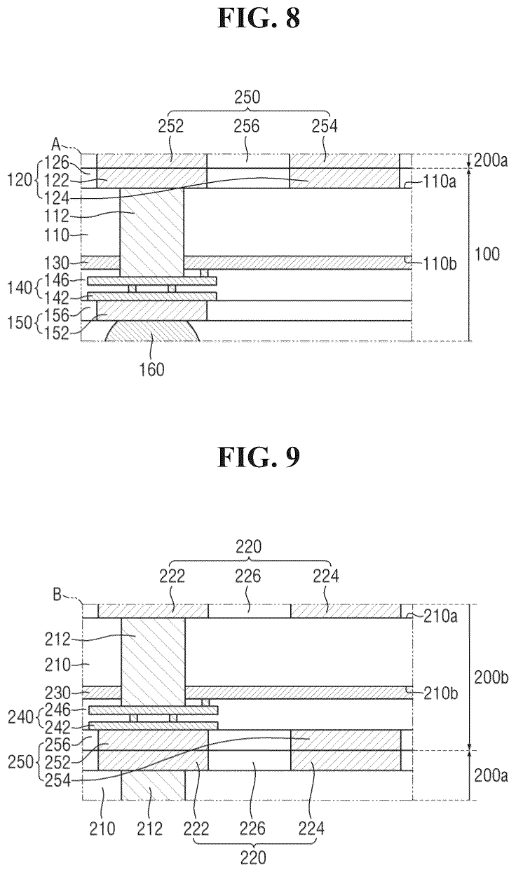

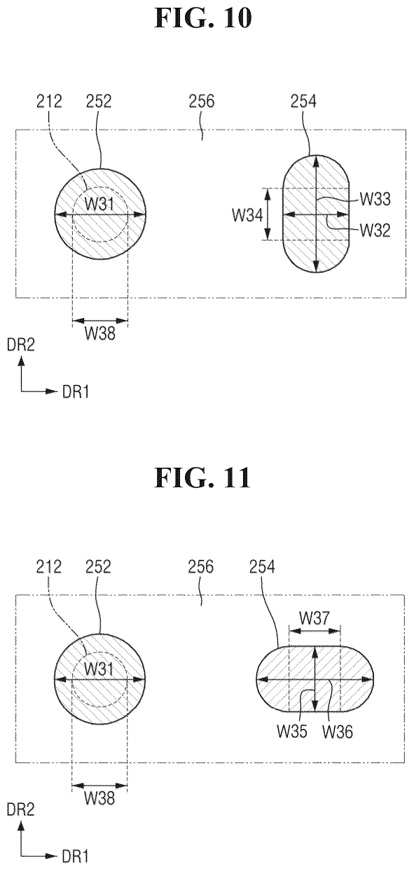

FIG. 8 is an enlarged view of the A area in FIG. 1. FIG. 9 is an enlarged view of the B area in FIG. 1. FIG. 10 and FIG. 11 are diagrams for illustrating a first lower dummy pad. For convenience of descriptions, differences thereof from those as described above using FIGS. 1 to 7 will be mainly described.

Referring to FIGS. 8 to 11, in the semiconductor package according to example embodiments of the present inventive concept, the second lower bonding layer 250 of each of the second semiconductor chips 200a to 200k may further include a first lower dummy pad 254.

The first lower dummy pad 254 may be disposed in the second lower bonding insulating film 256. The first lower dummy pad 254 is not electrically connected to the second through-via 212. The first lower dummy pad 254 does not contact the second through-via 212. In addition, the first lower dummy pad 254 may contact a dummy through-via extending through the second semiconductor substrate 210. Within the second lower bonding insulating film 256, a position of the first lower bonding pad 252 and a position of the first lower dummy pad 254 may vary.

The first lower dummy pad 254 may be made of a metal material, such as at least one of copper (Cu), tungsten (W), aluminum (Al), tungsten nitride (WN), tantalum nitride (TaN), and/or titanium nitride (TiN). However, the present inventive concept is not limited thereto.

For example, the first upper dummy pad 124 of the first semiconductor chip 100 and the first lower dummy pad 254 of the second semiconductor chip 200a adjacent thereto in the third direction DR3 may contact each other and may be bonded to each other in a copper-copper bonding scheme. For example, the first lower dummy pad 254 and the second upper dummy pad 224 adjacent thereto in the third direction DR3 may contact each other and be bonded to each other in a copper-copper bonding scheme.

In another example, the first upper dummy pad 124 of the first semiconductor chip 100 may contact the second lower bonding insulating film 256 of the second semiconductor chip 200a adjacent thereto in the third direction DR3. In another example, the second upper dummy pad 224 may contact the second lower bonding insulating film 256 adjacent thereto in the third direction DR3.

Referring to FIG. 10 and FIG. 11, in a plan view including the first direction DR1 and the second direction DR2, a size of an area of the second lower bonding pad 252 is substantially the same a size of an area of the first lower dummy pad 254, and the second lower bonding pad 252 and the first lower dummy pad 254 have different shapes from each other.

Descriptions about the second lower bonding pad 252, the first lower dummy pad 254, and widths W31, W32, W33, W34, and W38 in FIG. 10 may be substantially the same as the descriptions about the first upper bonding pad 122, the first upper dummy pad 124 and the widths W11, W12, W13, W14, and W18, respectively, as described above using FIG. 3

Descriptions about the second lower bonding pad 252, the first lower dummy pad 254, and widths W31, W35, W36, W37, and W38 in FIG. 11 may be substantially the same as the descriptions about the first upper bonding pad 122, the first upper dummy pad 124 and the widths W11, W15, W16, W17, and W18, respectively, as described above using FIG. 4.

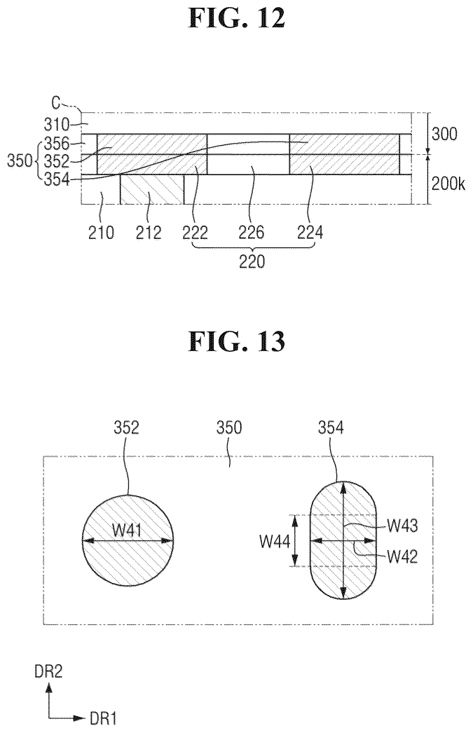

FIG. 12 is an enlarged view of the C area in FIG. 1. FIG. 13 is a diagram for illustrating a second lower dummy pad. For convenience of descriptions, differences thereof from those as described above using FIGS. 1 to 7 will be mainly described.

Referring to FIG. 12 and FIG. 13, in the semiconductor package according to example embodiments of the present inventive concept, the third semiconductor chip 300 may further include a second lower dummy pad 354.

The second lower dummy pad 354 may be disposed in the third lower bonding insulating film 356. The second lower dummy pad 354 is not electrically connected to the second through-via 212. Within the third lower bonding insulating film 356, a position of the third lower bonding pad 352 and a position of the second lower dummy pad 354 may vary.

The second lower dummy pad 354 may be made of a metal material, such as at least one of copper (Cu), tungsten (W), aluminum (Al), tungsten nitride (WN), tantalum nitride (TaN), and/or titanium nitride (TiN). However, the present inventive concept is not limited thereto.

For example, the second lower dummy pad 354 of the third semiconductor chip 300 and the second upper dummy pad 224 of the second semiconductor chip 200k that is adjacent thereto in the third direction DR3 may contact each other and be bonded to each other in a copper-copper bonding scheme. The second lower dummy pad 354 and the second upper dummy pad 224 that is adjacent thereto in the third direction DR3 may be in contact with each other and may be bonded to each other in a copper-copper bonding scheme.

In another example, the second lower dummy pad 354 of the third semiconductor chip 300 may contact the second lower bonding insulating film 256 of the second semiconductor chip 200k adjacent thereto in the third direction DR3.

Referring to FIG. 13, in a plan view including the first direction DR1 and the second direction DR2, a size of an of the third lower bonding pad 352 is substantially equal to a size of an area of the second lower dummy pad 354, and the third lower bonding pad 352 and the second lower dummy pad 354 have different shapes from each other.

Descriptions about the third lower bonding pad 352, the second lower dummy pad 354 and widths W41, W42, W43, and W44 in FIG. 13 may be substantially the same as the descriptions about the first upper bonding pad 122, the first upper dummy pad 124 and the widths W11, W12, W13, and W14, respectively, as described above using FIG. 3.

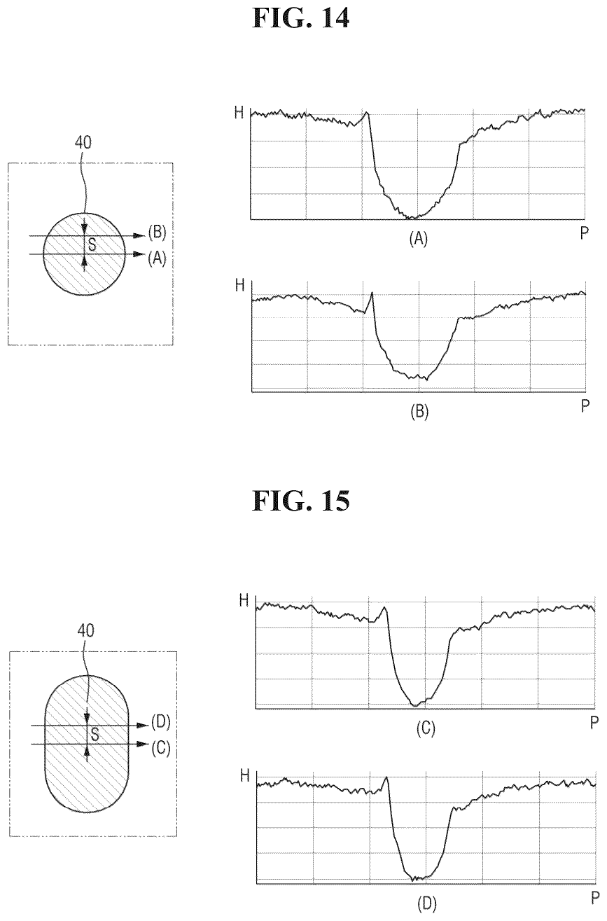

FIG. 14 and FIG. 15 are diagrams for illustrating effects of the semiconductor package according to example embodiments of the present inventive concept.

Referring to FIG. 14 and FIG. 15, a first line A is a line passing through a center of a dummy pad 40, and a second line B is a line spaced upwardly from the first line A by a spacing S.

For example, the dummy pad 40 in FIGS. 14 and 15 may be, for example, one of the first and second upper dummy pads 124 and 224, and the first and second lower dummy pads 254 and 354 in FIGS. 1 to 13. A size of an area of the dummy pad 40 (e.g., one of the first and second upper dummy pads 124 and 224, and the first and second lower dummy pads 254 and 354 in FIGS. 1 to 13) is substantially the same as a size of an area of a bonding pad (for example, one of the first and second upper bonding pads 122 and 222, and the first to third lower bonding pads 152, 252, and 352 in FIG. 1 to FIG. 13 having an area with a size that is substantially equal to a size of an area of the dummy pad 40). Thus, a dishing measurement value of the dummy pad 40 may represent a dishing value of the bonding pad.

Referring to FIG. 14, when the dummy pad 40 has a circular shape, a difference between a profile H of an upper surface of the dummy pad 40 based on a position P on the first line A and a profile H of the upper surface of the dummy pad 40 based on a position P on the second line B is large. In other words, a dishing value varies along a reference line for measuring the dishing (for example, the first line A or the second line B).

In addition, a difference between the profile H of the upper surface of the dummy pad 40 based on the position P on the first line A and the profile H of the upper surface of the dummy pad 40 based on the position P on the second line B when the dummy pad 40 has a shape including an area whose a maximum width is constant as shown in FIG. 15 is smaller than the difference between the profile H of the upper surface of the dummy pad 40 based on the position P on the first line A and the profile H of the upper surface of the dummy pad 40 based on the position P on the second line B when the dummy pad 40 has the circular shape as shown in FIG. 14. That is, an effect of the reference line for measuring the dishing (for example, the first line A or the second line B) on the dishing measurement value when the dummy pad 40 has a shape including an area whose a maximum width is constant as shown in FIG. 15 is smaller than that when the dummy pad 40 has the circular shape as shown in FIG. 14. Therefore, the semiconductor package according to example embodiments of the present inventive concept may measure the dishing more quickly and accurately.

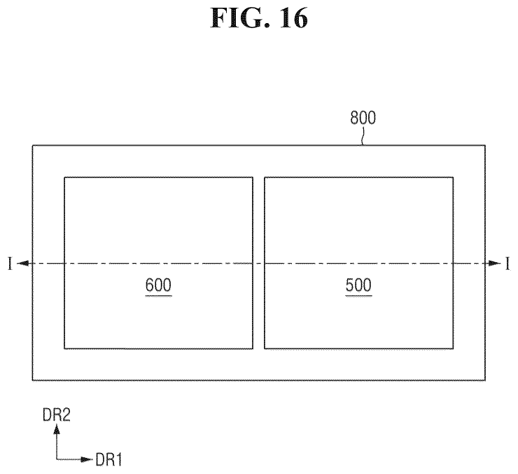

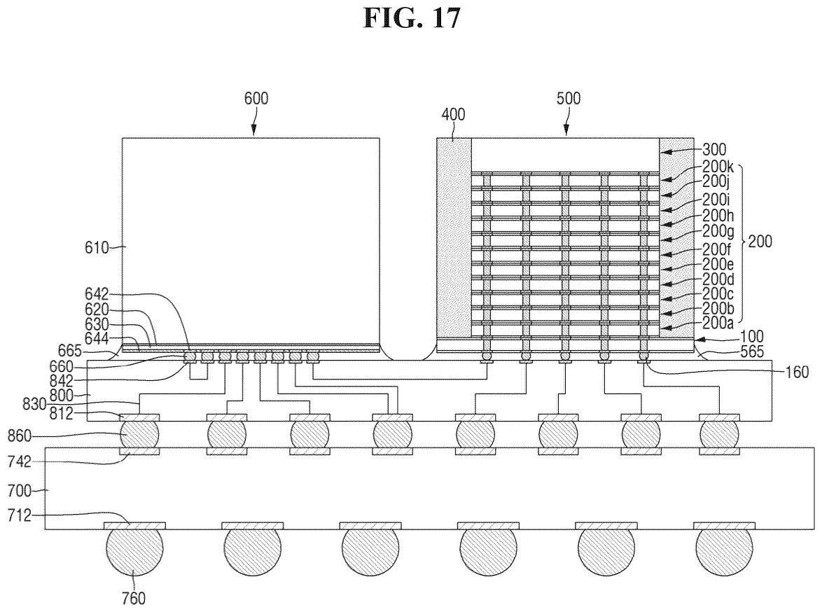

FIG. 16 is a plan view for illustrating a semiconductor package according to example embodiments of the present inventive concept. FIG. 17 is a cross-sectional view cut along a line I-I in FIG. 16. For convenience of descriptions, differences thereof from those as described above using FIGS. 1 to 15 will be mainly described. Redundant descriptions may be omitted or briefly described.

Referring to FIG. 16 and FIG. 17, a semiconductor package according to example embodiments of the present inventive concept may include a substrate 700, an interposer 800, a fourth semiconductor chip 600, and a semiconductor chip stack 500.

The substrate 700 may be a substrate for a semiconductor package. The substrate 700 may be, for example, a printed circuit board (PCB), a ceramic substrate, a tape wiring substrate, etc. The substrate 700 may include a first substrate pad 712 and a second substrate pad 742. The first substrate pad 712 may be disposed on a lower surface of the substrate 700, and the second substrate pad 742 may be disposed on an upper surface of the substrate 700. The first substrate pad 712 and the second substrate pad 742 may be electrically connected to each other via internal wirings of the substrate 700.

A second connection terminal 760 may be disposed on the first substrate pad 712 of the substrate 700. The second connection terminal 760 may be electrically connected to the first substrate pad 712. The second connection terminal 760 may include, for example, a solder ball, a bump, an under bump metallurgy (UBM), etc. The second connection terminal 760 may include metal such as tin (Sn). However, the present inventive concept is not limited thereto.

The interposer 800 may be disposed on the substrate 700. The interposer 800 may include a first interposer pad 812, a second interposer pad 842, and a wiring pattern 830. The first interposer pad 812 may be disposed on a lower surface of the interposer 800, and the second interposer pad 842 may be disposed on an upper surface of the interposer 800. The first interposer pad 812 and the second interposer pad 842 may be electrically connected to each other via the wiring pattern 830 that is disposed inside the interposer 800.

A third connection terminal 860 may be disposed between the interposer 800 and the substrate 700. The third connection terminal 860 may be disposed on the first interposer pad 812 of the interposer 800 and the second substrate pad 742 of the substrate 700. The third connection terminal 860 may be electrically connected to the first interposer pad 812 of the interposer 800 and the second substrate pad 742 of the substrate 700. Accordingly, the interposer 800 may be electrically connected to the substrate 700. The third connection terminal 860 may include, for example, a solder ball, a bump, an under bump metallurgy (UBM), etc. The third connection terminal 860 may include metal such as tin (Sn). However, the present inventive concept is not limited thereto.

The semiconductor chip stack 500 and the fourth semiconductor chip 600 may be disposed on the interposer 800. The semiconductor chip stack 500 and the fourth semiconductor chip 600 may be disposed on the upper surface of the interposer 800 while being spaced apart from each other. For example, the semiconductor chip stack 500 and the fourth semiconductor chip 600 may be spaced apart from each other in the first direction DR1.

The semiconductor chip stack 500 may be the semiconductor package as described above using FIGS. 1 to 13. The first connection terminal 160 may be disposed between the semiconductor chip stack 500 and the interposer 800. The first connection terminal 160 may be disposed on the first lower bonding pad 152 of the first semiconductor chip 100 and the second interposer pad 842 of the interposer 800. The first connection terminal 160 may be electrically connected to the first lower bonding pad 152 of the first semiconductor chip 100 and the second interposer pad 842 of the interposer 800. Accordingly, the semiconductor chip stack 500 may be electrically connected to the interposer 800.

A first underfill 565 may be disposed between the interposer 800 and the semiconductor chip stack 500. The first underfill 565 may fill a space between the interposer 800 and the semiconductor chip stack 500. The first underfill 565 may cover the first connection terminal 160. For example, the first underfill 565 may at least partially surround the first connection terminal 160.

The fourth semiconductor chip 600 may include a fourth semiconductor substrate 610, a third semiconductor device layer 620, a third chip wiring layer 630, a passivation film 644, and a chip pad 642. The fourth semiconductor chip 600 may be, for example, a logic semiconductor chip.

The fourth semiconductor substrate 610 may be made of, for example, bulk silicon or SOI (silicon-on-insulator). In addition, as an example, the fourth semiconductor substrate 610 may be a silicon substrate, or may include a material other than silicon, such as, but not limited to, silicon germanium, silicon germanium on insulator (SGOI), indium antimonide, lead telluride compound, indium arsenide, indium phosphide, gallium arsenide or gallium antimonide.

The third semiconductor device layer 620 may be disposed on the fourth semiconductor substrate 610. The third semiconductor device layer 620 may be disposed on a lower surface of the fourth semiconductor substrate 610. The third semiconductor device layer 620 may include various microelectronic elements.

The third chip wiring layer 630 may be disposed on the third semiconductor device layer 620. The third chip wiring layer 630 may be electrically connected to the third semiconductor device layer 620. In a similar manner to the first and second chip wiring layers 130 and 230, the third chip wiring layer 630 may include a third chip inter-wiring insulating film and a third chip wiring structure that is disposed in the third chip inter-wiring insulating film. The third semiconductor device layer 620 may contact the third chip wiring structure.

The passivation film 644 may be disposed on the third chip wiring layer 630. At least a portion of the chip pad 642 might not be covered with the passivation film 644 so as to be exposed. A lower surface of the chip pad 642 might not be covered with the passivation film 644 so as to be exposed. The chip pad 642 may be electrically connected to the chip wiring layer 530. The chip pad 642 may contact the third chip wiring structure.

A fourth connection terminal 660 may be disposed between the fourth semiconductor chip 600 and the interposer 800. The fourth connection terminal 660 may be disposed on the chip pad 642 of the fourth semiconductor chip 600 and the second interposer pad 842 of the interposer 800. The fourth connection terminal 660 may be electrically connected to the chip pad 642 of the fourth semiconductor chip 600 and the second interposer pad 842 of the interposer 800. Accordingly, the fourth semiconductor chip 600 may be electrically connected to the interposer 800. The semiconductor chip stack 500 and the fourth semiconductor chip 600 may be electrically connected to each other via the interposer 800. The fourth connection terminal 660 may include, for example, a solder ball, a bump, an under bump metallurgy (UBM), etc. The fourth connection terminal 660 may include metal such as tin (Sn). However, the present inventive concept is not limited thereto.

A second underfill 665 may be disposed between the interposer 800 and the fourth semiconductor chip 600. The second underfill 665 may fill a space between the interposer 800 and the fourth semiconductor chip 600. The second underfill 665 may cover the third connection terminal 660. For example, the second underfill 665 may at least partially surround the third connection terminal 660. Each of the first underfill 565 and the second underfill 665 may include, for example, an insulating polymer material such as EMC (epoxy molding compound). However, the present inventive concept is not limited thereto.

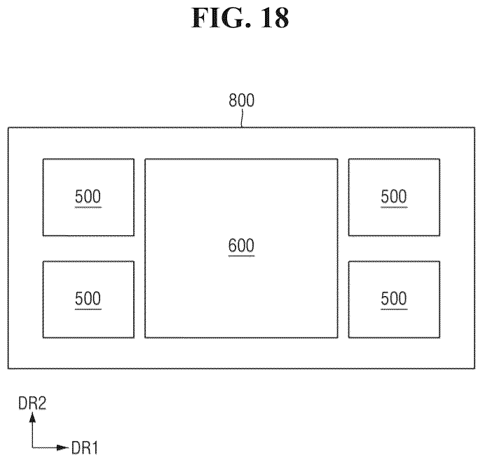

FIGS. 18 to 20 are plan views for illustrating a semiconductor package according to example embodiments of the present inventive concept. For convenience of descriptions, differences thereof from those as described above using FIGS. 1 to 17 will be mainly described. In addition, redundant descriptions may be omitted or briefly discussed.

Referring to FIGS. 18 to 20, the semiconductor chip stack 500 may be the semiconductor package as described using FIGS. 1 to 13.

Referring to FIG. 18, a semiconductor package according to example embodiments of the present inventive concept may include a plurality of semiconductor chip stacks 500 and the fourth semiconductor chip 600. The plurality of semiconductor chip stacks 500 and the fourth semiconductor chip 600 may be disposed on the interposer 800. The plurality of semiconductor chip stacks 500 may be arranged around the fourth semiconductor chip 600.

For example, four semiconductor chip stacks 500 may be arranged around the fourth semiconductor chip 600. Two semiconductor chip stacks 500 may be respectively disposed on each of two opposing sides in the first direction DR1 of the fourth semiconductor chip 600, and may be spaced apart from each other in the second direction DR2. The fourth semiconductor chip 600 may be disposed between the semiconductor chip stacks 500.

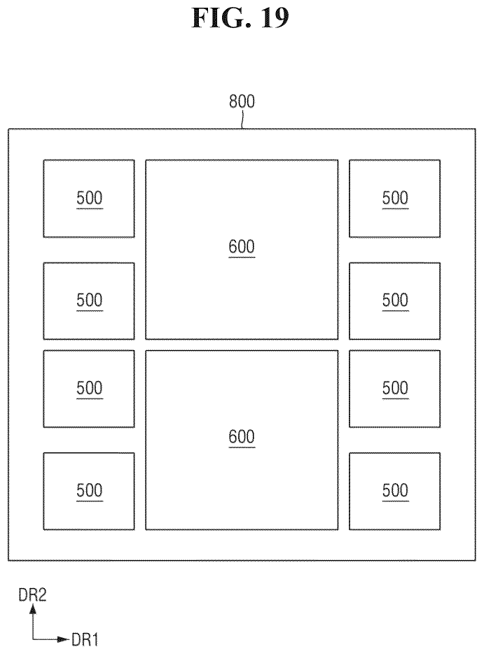

Referring to FIG. 19, a semiconductor package according to example embodiments of the present inventive concept may include a plurality of semiconductor chip stacks 500 and a plurality of fourth semiconductor chips 600. The plurality of semiconductor chip stacks 500 and the plurality of fourth semiconductor chips 600 may be disposed on the interposer 800.

For example, two fourth semiconductor chips 600 may be disposed adjacent to each other and may be spaced apart from each other in the second direction DR2. Four semiconductor chip stacks 500 may be arranged around one fourth semiconductor chip 600. Regarding each fourth semiconductor chip 600, two semiconductor chip stacks 500 may be respectively disposed on each of two opposing sides in the first direction DR1 of the fourth semiconductor chip 600, and the two semiconductor chip stacks 500 may be spaced apart from each other in the second direction DR2. Each of the fourth semiconductor chips 600 may be disposed between the semiconductor chip stacks 500.

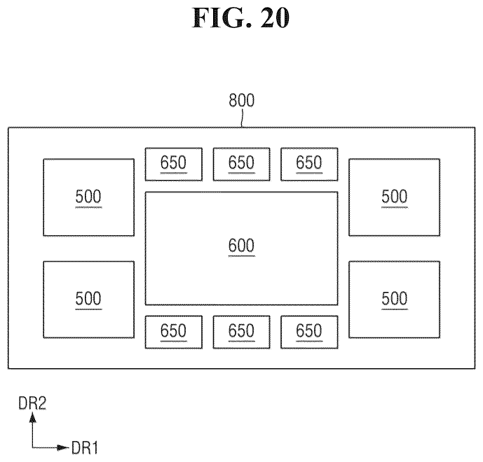

Referring to FIG. 20, a semiconductor package according to example embodiments of the present inventive concept may include a plurality of semiconductor chip stacks 500, the fourth semiconductor chip 600, and a plurality of chiplets 650. The plurality of semiconductor chip stacks 500, the fourth semiconductor chip 600, and the plurality of chiplets 650 may be disposed on the interposer 800. The plurality of semiconductor chip stacks 500 and the plurality of chiplets 650 may be arranged around the fourth semiconductor chip 600. Each of the plurality of chiplets 650 may include, for example, one of a process chip, a logic chip, or a memory chip.

For example, six chiplets 650 may be arranged around the fourth semiconductor chip 600. Three chiplets 650 may be disposed on each of two opposing sides in the second direction DR2 of the fourth semiconductor chip 600, and may be spaced apart from each other in the first direction DR1. The fourth semiconductor chip 600 may be disposed between the chiplets 650. Four semiconductor chip stacks 500 may be arranged around the fourth semiconductor chip 600. Two semiconductor chip stacks 500 may be respectively disposed on each of two opposing sides in the first direction DR1 of the fourth semiconductor chip 600, and may be spaced apart from each other in the second direction DR2. The fourth semiconductor chip 600 may be disposed between the semiconductor chip stacks 500.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor chip comprising:
a semiconductor substrate including a first surface and a second surface that is opposite to the first surface;
a through-via disposed in the semiconductor substrate;
a first bonding pad disposed on the first surface of the semiconductor substrate and electrically connected to the through-via;
a first dummy pad disposed on the first surface of the semiconductor substrate and insulated from the through-via; and
a second bonding pad disposed on the second surface of the semiconductor substrate and electrically connected to the through-via,
wherein a first maximum width of the first bonding pad is greater than a second maximum width in a first direction of the first dummy pad and is smaller than a third maximum width in a second direction of the first dummy pad, and
wherein the first direction is substantially perpendicular to the second direction.

2. The semiconductor chip of claim 1, wherein the first dummy pad may include an area having a width in the first direction that is constant and is substantially equal to the second maximum width.

3. The semiconductor chip of claim 1, wherein a size of an area of the first bonding pad is substantially equal to a size of an area of the first dummy pad.

4. The semiconductor chip of claim 1, wherein the second maximum width in the first direction of the first dummy pad is greater than a fourth maximum width of the through-via.

5. The semiconductor chip of claim 1, further comprising a semiconductor device layer disposed on the second surface of the semiconductor substrate and electrically connected to the through-via.

6. The semiconductor chip of claim 1, further comprising a second dummy pad disposed on the second surface of the semiconductor substrate and insulated from the through-via.

7. The semiconductor chip of claim 6, wherein a size of an area of the second bonding pad is substantially equal to a size of an area of the second dummy pad, and a shape of the second bonding pad is different from a shape of the second dummy pad.

8. A semiconductor package comprising:
a first semiconductor chip including:
a first bonding insulating film; and
a first bonding pad and a first dummy pad disposed in the first bonding insulating film; and
a second semiconductor chip including:
a second bonding insulating film disposed on the first bonding insulating film; and
a second bonding pad disposed in the second bonding insulating film and in contact with the first bonding pad,
wherein a size of an area of the first bonding pad is substantially equal to a size of an area of the first dummy pad,
wherein a first maximum width of the first bonding pad is different from each of a second maximum width in a first direction of the first dummy pad and a third maximum width in a second direction of the first dummy pad, and
wherein the first direction is substantially perpendicular to the second direction.

9. The semiconductor package of claim 8, wherein the first maximum width of the first bonding pad is greater than the second maximum width of the first dummy pad and is smaller than the third maximum width of the first dummy pad.

10. The semiconductor package of claim 8, wherein the first dummy pad may include an area having a width in the first direction that is is constant along the second direction and is substantially equal to the second maximum width.

11. The semiconductor package of claim 8, wherein the first bonding pad has a circular shape, and the first dummy pad has an elliptical shape.

12. The semiconductor package of claim 8, wherein the first dummy pad is in contact with the second bonding insulating film.

13. The semiconductor package of claim 8, wherein the second semiconductor chip further includes a second dummy pad disposed in the second bonding insulating film,
wherein a size of an area of the second bonding pad is substantially equal to a size of an area of the second dummy pad, wherein the second bonding pad has a circular shape, and the second dummy pad has an elliptical shape.

14. The semiconductor package of claim 13, wherein the second dummy pad is in contact with the first dummy pad.

15. A semiconductor package comprising:
a first semiconductor chip; and
a chip stack including a plurality of second semiconductor chips that are stacked on the first semiconductor chip,
wherein each of the plurality of second semiconductor chips includes:
a semiconductor substrate including a first surface and a second surface that is opposite to the first surface;
a through-via extending through the semiconductor substrate;
a first bonding insulating film disposed on the first surface of the semiconductor substrate;
a first bonding pad disposed in the first bonding insulating film and electrically connected to the through-via;
a first dummy pad disposed in the first bonding insulating film and insulated from the through-via;
a second bonding insulating film disposed on the second surface of the semiconductor substrate; and
a second bonding pad disposed in the second bonding insulating film and electrically connected to the through-via,
wherein the first bonding pad of a first second semiconductor chip of the plurality of second semiconductor chips and the second bonding pad of a second second semiconductor chip of the plurality of second semiconductor chips are adjacent to each other and are in contact with each other,
wherein a size of an area of the first bonding pad is substantially equal to a size of an area of the first dummy pad, and
wherein the first dummy pad includes a portion that has a width in a first direction that is substantially equal to a second maximum width of the first dummy pad that is smaller than a first maximum width of the first bonding pad.

16. The semiconductor package of claim 15, wherein the second maximum width is in a range of about 0.5 times to about 0.8 times of the first maximum width.

17. The semiconductor package of claim 16, wherein the first dummy pad has a third maximum width in the second direction, and
wherein the third maximum width is about 1.6 times of the second maximum width.

18. The semiconductor package of claim 15, wherein the first dummy pad of the first second semiconductor chip of the plurality of second semiconductor chips is in contact with the second bonding insulating film of the second semiconductor chip of the plurality of second semiconductor chips.

19. The semiconductor package of claim 15, wherein the second maximum width of the first dummy pad is greater than a fourth maximum width of the through-via.

20. The semiconductor package of claim 15, wherein each of the plurality of second semiconductor chips further includes a second dummy pad disposed in the second bonding insulating film and insulated from the through-via, and
wherein the second dummy pad is in contact with the first dummy pad.
